(19) United States
(12) Patent Application Publication
(10) Pub. No.: US 2013/0279111 A1
(43) Pub. Date: Oct. 24, 2013

(54) BACKPLANE DESIGN FOR MINIATURE CONFIGURABLE COMMUNICATIONS DATA CENTER

(71) Applicant: Cooper G. Lee, Laguna Niguel, CA (US)

(72) Inventor: Cooper G. Lee, Laguna Niguel, CA (US)

(21) Appl. No.: 13/866,426

(22) Filed: Apr. 19, 2013

Related U.S. Application Data
(60) Provisional application No. 61/635,479, filed on Apr. 19, 2012.

(51) Int. Cl. G06F 1/18; H05K 1/02; G06F 1/20

(52) U.S. Cl. CPC G06F 1/188; G06F 1/20; H05K 1/02
USPC 361/679.47; 361/679.02; 361/679.54; 361/760

(57) ABSTRACT

A ruggedized communications data center is provided. The ruggedized communications data center includes a ruggedized enclosure having a main body. The ruggedized enclosure includes a secured sealed access cover affixed to the main body, a backplane support structure within the main body, and a backplane coupled to the backplane support structure within the main body. The backplane includes a plurality of connectors to connect with a plurality of cards including at least one connector to connect to a power supply card, at least one connector to connect to a switch matrix card, and at least one connector to connect to a module card. The backplane also includes a first plurality of electrical connections to electrically connect a power supply card with a switch matrix card and a module card and a second plurality of electrical connections to electrically connect a switch matrix card with a module card.

### CROSS REFERENCE TO RELATED APPLICATIONS

This application claims priority under 35 USC 119(e) to U.S. provisional patent application No. 61/635,479 filed Apr. 19, 2012 and titled BACKPLANE DESIGN FOR MINIATURE CONFIGURABLE COMMUNICATIONS DATA CENTER, which is hereby incorporated herein by reference in its entirety.

### BACKGROUND

1. Technical Field

The present invention relates to a backplane for a miniature and/or rugged data center.

2. Discussion

Data centers are computer facilities that provide infrastructure necessary to support a network of computers and corresponding users. This infrastructure is generally composed of a plurality of subsystems including server equipment, power conditioning equipment, cooling equipment, and networking equipment (e.g., switches or routers). These subsystems are typically operatively connected together through a series of cables. Conventional components included in the subsystems are designed to operate in a strictly-controlled physical environment. This physical environment is typically a climate controlled environment that is substantially free of excessive dirt, debris, or particulates and vibration.

A data center may be organized by subsystem into functional “trays” of a standard size (e.g., height, depth, and width). These trays comprise the necessary components of a respective data center subsystem. The trays are stored in vertical racks or cabinets. The cabinets provide a mechanical enclosure for tray storage in the controlled environment (e.g., within a controlled room in a building). The cabinets offer equipment little protection from the environment outside the cabinets.

### SUMMARY OF INVENTION

In accordance with at least one aspect of the embodiments disclosed herein, it is recognized that the standard data center does not enable data center placement outside of a carefully controlled, stationary and secure environment. To overcome these location requirements, a ruggedized backplane and accompanying enclosure for a data center is provided. The backplane may include a plurality of high-density multiple-contact connectors that accept input from a plurality of cards, each card representing one of various data center subsystems. The backplane may further be affixed within a ruggedized enclosure to offer protection from environmental elements and a heat sink to facilitate heat dissipation. In at least one embodiment, a ruggedized communications data center is provided.

The ruggedized communications data center includes a ruggedized enclosure having a main body. The ruggedized enclosure includes a removably secured sealed access cover affixed to the main body, a backplane support structure within the main body, and a backplane removably coupled to the backplane support structure within the main body. The backplane to includes a plurality of connectors to removably connect with a plurality of cards including at least one connector to removably connect to a power supply card, at least one connector to removably connect to a switch matrix card, and at least one connector to connect to a module card. The backplane also includes a first plurality of electrical connections to electrically connect a power supply card with a switch matrix card and a module card and a second plurality of electrical connections to electrically connect a switch matrix card with a module card.

In the ruggedized communications data center the backplane may include a printed circuit board. The backplane may further include a first high-density multiple-contact connector configured to removably connect with a power supply card, a second high-density multiple-contact connector configured to removably connect with a switch matrix card, a third high-density multiple-contact connector configured to removably connect with a module card, a plurality of power distribution traces arranged to distribute power from the first high-density multiple-contact connector to the second high-density multiple contact connector and the third high-density multiple contact connector, and a plurality of communication traces arranged to operatively connect the second high-density multiple-contact connector and the third high-density multiple-contact connector.

In the ruggedized communications data center, the backplane may be a passive backplane. The backplane may further include at least one fan port. The backplane may further include a serial port.

In the ruggedized communications data center, the plurality of power distribution traces may be arranged in a star configuration from the first high-density multiple-contact connector to the second high-density multiple-contact connector and the third high-density multiple-contact connector. The plurality of communication traces may be arranged in a star configuration from the second high-density multiple-contact connector to the first high-density multiple-contact connector and the third high-density multiple-contact connector.

In the ruggedized communications data center, the module card may be a first module card and the backplane may further include a fourth high-density multiple-contact connector configured to receive input from a second module card.

In the ruggedized communications data center, the ruggedized enclosure may be constructed from aluminum. The ruggedized enclosure may be sealed from outside debris and humidity. The ruggedized enclosure may further include a heat sink affixed to the main body of the ruggedized enclosure. The heat sink may be designed to dissipate 50 Watts of to heat per card installed in the backplane. The ruggedized enclosure may be designed to enable communications data center operation during ambient temperatures ranging from −40 degrees centigrade to 74 degrees centigrade. The ruggedized enclosure may be designed to enable communications data center operation in altitudes in excess of 3,000 meters.

In the ruggedized communications data center, the removably sealed access cover affixed to the main body of the ruggedized enclosure may include at least one port. The at least one port of the removably sealed access cover may include an Ethernet port. The backplane may include at least one port operatively connected to the at least one port of the removably sealed access cover.

In the ruggedized communications data center, the ruggedized enclosure further includes heat pipes and a heat sink. The heat sink may be located a distance from the main body. The heat pipes may be operatively connected to the heat sink located some distance from the ruggedized enclosure.

In accordance with another aspect of the present invention, a communications center backplane is provided. The backplane comprises a plurality of connectors to removably connect with a plurality of cards, a first plurality of electrical connections and a second plurality of electrical connections. The plurality of connectors include at least one first connector having a power channel and a communication channel to connect to a power supply card, at least one second connector having a power channel and a communication channel to connect to a switch matrix card, and at least one third connector having a power channel and a communication channel to connect to a module card. The first plurality of electrically connect the power channel of the at least one first connector to the power channel of the at least one second connector and the power channel of the at least one third connector. The second plurality of electrical connections electrically connect the communication channel of the at least one second connector with the communication channel of the at least one first connector and the communication channel of the at least one third connector.

Still other aspects, embodiments and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Any embodiment disclosed herein may be combined with any other embodiment. References to “an embodiment,” “an example,” “some embodiments,” “some examples,” “an alternate to embodiment,” “various embodiments,” “one embodiment,” “at least one embodiment,” “this and other embodiments” or the like are not necessarily mutually exclusive and are intended to indicate that a particular feature, structure, or characteristic described in connection with the embodiment may be included in at least one embodiment. The appearances of such terms herein are not necessarily all referring to the same embodiment.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and examples, and are incorporated in and constitute a part of this specification, but are not intended as a definition of the limits of the embodiments disclosed herein. The drawings, together with the remainder of the specification, serve to explain principles and operations of the described and claimed aspects and examples. In the figures, each identical or nearly identical component that is illustrated in various figures is represented by a like numeral. For purposes of clarity, not every component may be labeled in every figure. In the figures:

FIG. 1 illustrates an example wiring schematic of a backplane design;

FIG. 2 illustrates an example ruggedized enclosure with the accompanying backplane installed;

FIG. 3 illustrates another example ruggedized enclosure with the accompanying backplane installed;

FIG. 4 illustrates another example ruggedized enclosure with the accompanying backplane installed;

FIG. 5 illustrates another example ruggedized enclosure with the accompanying backplane installed;

FIG. 6 illustrates another example ruggedized enclosure with the accompanying backplane installed; and

FIG. 7 illustrates another example ruggedized enclosure with the accompanying backplane installed.

### DETAILED DESCRIPTION

It is to be appreciated that examples of the methods and apparatuses discussed herein are not limited in application to the details of construction and the arrangement of components set forth in the following description or illustrated in the accompanying drawings. The methods and apparatuses are capable of implementation in other examples and of being practiced or of being carried out in various ways. Examples of specific implementations are provided herein for illustrative purposes only and are not intended to be limiting. In particular, acts, elements and features discussed in connection with any one or more examples are not intended to be excluded from a similar role in any other examples.

Also, the phraseology and terminology used herein is for the purpose of description and should not be regarded as limiting. Any references to examples or elements or acts of the systems and methods herein referred to in the singular may also embrace examples including a plurality of these elements, and any references in plural to any example or element or act herein may also embrace examples including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Embodiments of the present invention relate generally to a small form factor high-density communications data center backplane and corresponding enclosure enabling a communications data center to operate in a variety of harsh environments. As used herein, a communications data center includes a backplane comprising connectors to each of a power supply subsystem or card, a switch matrix subsystem or card, and a module subsystem or card. The module subsystem or card may include virtual or dedicated server module cards, radio frequency communication module cards (e.g., supporting IEEE 802.11 Wi-Fi or cellular 4G-LTE protocols), Ethernet switching module cards, integrated services router module cards, video recording and archiving module cards, and analog input or output module cards. The backplane provides durable connections between the plurality of subsystems that comprise a communications data center. The enclosure provides a layer of protection from outside environmental elements that may affect the communications data center's operation. The variety of harsh environments where the backplane and enclosure may be installed and operate include, but are not limited to, mobile environments (e.g., a train, a plane, a bus, a boat, and a car), underground environments, and aboveground environments that are at least partially exposed to the external environment (e.g., mounted on a pole or on a platform).

In one embodiment, the backplane is configured to support a communications data center in a mobile environment. The communications data center is configured to communicate with an Internet Service Provider (ISP) and provide constant Internet connectivity to a plurality of users within the mobile environment. Communication between the communications data center and the ISP need not be solely through a wired connection. The connection may include a wireless communication link between a plurality of stationary sources outside the mobile environment and a receiver (e.g., an antenna) located in the mobile environment as described in Patent Publication US2008/0125129, which is hereby incorporated herein by reference in its entirety. The communications data center may have a connection with an antenna in the mobile environment (e.g., on the roof of a train) to establish the communication link with the plurality of stationary sources and subsequently the ISP. The communications data center may also connect to a second antenna within the mobile environment to provide constant wireless internet connectivity to users within the mobile environment (e.g., passengers on a train).

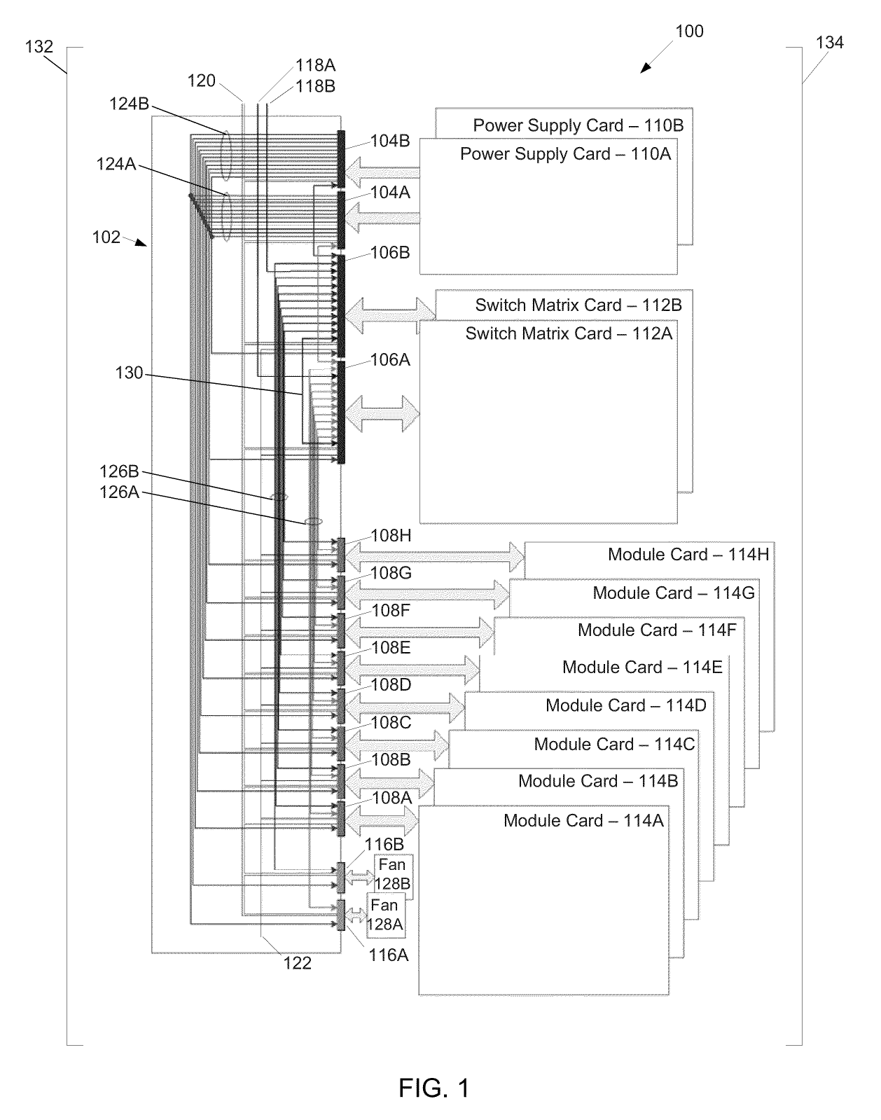

FIG. 1 illustrates such an embodiment of the backplane within the context of a data center 100. As shown, the data center 100 of FIG. 1 includes a backplane 102, management Ethernet ports 118A-B, a JTAG port 120, a synchronization port 122, power distribution traces 124A-B, communication traces 126A-B, a plurality of high-density multiple-contact connectors 104A-B, 106A-B, and 108A-H, a plurality of cards 110A-B, 112A-B, and 114A-H, fan ports 116A-B, fans 128A-B, failover traces 130, a front side 134, and a back side 132.

The backplane 102 may be fabricated from a variety of materials and may perform a variety of functions. For instance, the backplane 102 may be a printed circuit board (PCB) assembly. A PCB is a board that may be constructed out of composite materials to provide the necessary structure to support electrical components and “traces” between the electrical components. The traces are conductors located within or on the PCB to enable an electrical connection between any set of given points on the PCB. The backplane 102 may enable communication and power transfer between various devices integral with or connected to the backplane 102. The backplane 102 may enable this communication in an “active” or “passive” fashion. A passive backplane does not have any intervening components between various devices connected to the board. A passive backplane, for example, is only composed of a board, basic circuit elements, traces and any necessary external connections (e.g., ports or connectors). In contrast, an active backplane has some form of programmable capability. An active backplane, for example, may include Integrated Circuit (IC) chips on the backplane 102 that buffer the communication between two devices connected to the backplane. In addition, the backplane 102, in either active backplane embodiments or passive backplane embodiments, may include non-volatile data storage, such as an Identification Programmable Read Only Memory (IDPROM), storing information that uniquely identifies the backplane.

The backplane 102 may have, in addition to traces, a plurality high-density multiple-contact connectors 104A-B, 106A-B, and 108A-H. A high-density multiple-contact connector may include a multiple-contact connector with at least 27.5 to 82 differential pairs per linear inch (11-32 differential pairs per linear centimeter) and having specified impedance (e.g., 85 Ohms or 100 Ohms). Each of the high-density multiple-contact connectors may include a “socket” or a corresponding “plug.” The socket may be affixed to the backplane 102 and may include a plurality of “pins” electrically connected to respective traces on the backplane 102. Each pin provides an electrical contact to connect a device to a trace on or within the backplane. The pins may be further grouped into “channels” based on the function of each specific pin. For example, a series of pins that provide power to a device may be grouped into a power channel. It is appreciated that a series of pins that enable communication to a device may be grouped into a communication channel. The socket may also include Electrostatic Discharge (ESD) pins to safely discharge static electricity.

In addition, the length of each pin may vary based upon the specific function performed by the pin. For example, pins connecting a device to ground may be longer than other pins to ensure that the pins connecting the device to ground connect first. Varying the length of the pins as described may enable the devices to be hot-swappable. The pins lengths may include at least three different lengths to enable hot-swapping devices. Hot-swappable devices are devices that may be connected or disconnected during system operation. Additional presence detection pins may be included in the socket to hasten the rate at which the communications data center may detect the addition or removal of devices from the communications data center.

The plurality of pins and subsequent channels may be surrounded by a non-conducting material that provides structural support to the connector and, in conjunction with the pins, form the socket. The corresponding plug may be affixed to a device and may include a receptacle for each pin in the corresponding socket. Each receptacle may be electrically connected to the relevant components on the device and may be configured to receive and connect with a pin from the corresponding socket. The receptacles may also be surrounded by a non-conducting material to provide structural support to the plug and to function as an insulator between each of the pin receptacles. Suitable high-density multiple-contact connectors include the XCEDE family of connectors available from Amphenol Corporation.

It is appreciated that the high-density multiple-contact connectors described may be altered to suit the application. For example, the socket may be affixed to the device and the plug may be affixed to the backplane 102. In addition, backplane 102 may have any number of high-density multiple-contact connectors and is not limited to the number of connectors illustrated in FIG. 1. The high-density multiple-contact connectors may also include a latching mechanism to further ruggedize the connection between each card and the backplane. The latching mechanism may comprise a clip on the device that removably engages a lip on the high-density multiple-contact connector on the backplane. The clip may be constructed out of any pliable materials including, but not limited to, polyvinyl chloride (PVC) based plastics.

The plurality of high-density multiple-contact connectors 104A-B, 106A-B, and 108A-H facilitate the connection between the backplane 102 and the “cards” 110A-B, 112A-B, and 114A-H directly connected to the board of the backplane. Cards are devices that perform any subset of the plurality of functions necessary for communications data center operation. Each card includes one or more printed circuit boards and associated integrated circuits for performing a set of functions such as, but not limited to, power conditioning, circuit switching, and information routing. The cards may be directly connected to the sockets affixed to the backplane 102 through plugs affixed to each card. The cards may be grouped into a plurality of types based upon the communications data center subsystem function that the card performs. The card types accepted by the backplane 102 may include power supply cards 110A-B, switch matrix cards 112A-B, and module cards 114A-H. It is appreciated that the plurality of high-density multiple-contact connectors may have the same pin layout or construction for each type of card supported by the backplane. For example, the high-density multiple-contact connectors 104A-B for two power supply cards 110A-B may be identical while the connector for a switch matrix card 106A may have a different pin layout or construction. In addition, the plurality of high-density multiple-contact connectors may have the same pin layout or construction for all types of cards or any subset of types.

The backplane 102 may accept a power supply card 110A through a high-density multiple-contact connector. The power supply card 110A may accept “dirty” power from an external source and improve its characteristics to get “clean” power. In certain embodiments, to the power supply card includes two distinct power inputs capable of receiving power from two distinct sources of power. Clean power is power that meets the specifications required by the plurality of devices operatively connected to the backplane 102. In contrast, dirty power is power received from an external power source that may or may not meet the requirements required by the plurality of devices operatively connected to the backplane 102. The clean power received by the backplane 102 from the power supply card 110A may be distributed to the other cards on the board through a set of power distribution traces 124A. The set of power distribution traces 124A may be configured in a star configuration from the high-density multiple-contact connector 104A and the high-density multiple-contact connectors accepting input from switch matrix cards 106A-B or module cards 108A-H. The received clean power may be at any voltage level, current rating, and current type (e.g., alternating current and direct current) commensurate with the specific needs of the communications data center or its components. The voltages accepted by the backplane may include the voltages 54 Volts and 24 Volts. The backplane may also accept any given voltage or current rating at the set of power distribution traces 124A within the backplane to facilitate distribution to the plurality of cards operatively connected to the backplane. It is appreciated that the backplane 102 may accept a second power supply card 110B for redundancy. The backplane 102 may also include a second set of power distribution traces 124B to distribute power from the second power supply card 110B.

It is appreciated that the specific dirty power voltages accepted by the power supply card may vary based on the application. In a heavy rail application, the voltages accepted may range from 28 Volts to 42 Volts with a nominal value of 36 Volts. In a commuter rail application, the voltages accepted may range from 58 Volts to 90 Volts with a nominal value of 72 Volts. In European rail applications, the accepted voltages may range from 78 Volts to 130 Volts with a nominal value of 110 Volts. It is appreciated that the dirty power may be sourced from a variety of local power sources outside a pre-existing power utility network including, but not limited to, solar cells, wind turbines, and batteries. The secondary power supply card 110B may or may not have the same dirty power source or sources as the primary power supply card 110A. The power received by the backplane 102 from the secondary power source 110B on traces 124B may or may not be at the same voltage and current rating as the power received from the primary source 110A on traces 124A. The power supply cards may also have programmable capabilities. The programmable capabilities of the power supply may include the capability to internally monitor and transmit performance data such to as, but not limited to, power supply temperature, power quality metrics, and efficiency. The programmable capabilities of the power supply may further include setting individually adjustable protection against excessive current flow into each of the power distribution traces 124A or 124B.

The backplane 102 may also accept a first switch matrix card 112A. The first switch matrix card 112A enables communication between the plurality of cards operatively connected to the backplane 102 through a first set of communication traces 126A in a star configuration between the first switch matrix card high-density multiple-contact connector 106A and the plurality of other high-density multiple-contact connectors 104A-B and 108A-H. It is appreciated that the backplane may include a second switch matrix card 112B, a second set of communication traces arranged in a star configuration 126B, and a second switch matrix high-density multiple-contact connector 106B for redundancy. The first or second switch matrix cards may provide a plurality of communication connections to the module cards operatively connected to the backplane through the first and second set of communication traces 126A-B. The plurality of communication connections enabled by communication traces 126A-B may include Ethernet connections, serial port connections, and Keyboard, Video, Mouse, Universal Serial Bus (KVM+) connections. The Ethernet connections enabled by the first set of communication traces 126A may include a first Ethernet connection (e.g., primary Ethernet A) configured to communicate data generated or processed by any module card between the module card and the switch first matrix card and a second Ethernet connection (e.g., management Ethernet A) configured to communicate data for system management between any other card or fan 128A-B and the first switch matrix card. The Ethernet connections enabled by the second set of communication traces 126B may include third Ethernet connection (e.g., primary Ethernet B) configured to communicate data generated or processed by any module card between the module card and the second switch matrix card and a fourth Ethernet connection (e.g., management Ethernet B) configured to communication data for system management between any other card or fan 128A-B and the second switch matrix card. The aggregated data from the module cards communicated over primary Ethernet A or primary Ethernet B may be transmitted externally via a plurality of Ethernet ports on the faceplate of the first or second switch matrix cards. The Ethernet ports on the faceplate of the switch matrix card may accommodate Small Formfactor Pluggable (SFP) optical transceivers for connection to optical fiber data links. The first or second switch matrix cards may advantageously route aggregated data between to primary Ethernet A and primary Ethernet B as well as route aggregated data among the plurality of module cards using primary Ethernet A or primary Ethernet B. In addition, data may be routed between the first switch matrix card and the second switch matrix card through failover traces 130. The system management data communicated over management Ethernet A or management Ethernet B connections may be received externally from an Ethernet port on the faceplate of the first or second switch matrix cards or received from a management Ethernet port 118A in the case of management Ethernet A or management Ethernet port 118B in the case of management Ethernet B on the backplane 102.

The management Ethernet A and management Ethernet B connections for communicating system management data may be made available to all cards operatively connected to the backplane including the fans 128A-B. The serial port connections may include a first serial port connection enabled by the first set of communication traces 126A and a second serial port connection enabled by the second set of communication traces 126B. The serial port connections may communicate module card configuration data between any module card and the first or second switch matrix cards. The serial port connections may be made available via a serial port compliant with the RS232 standard on the faceplate of the first or second switch matrix cards or on the backplane. The KVM+ connections may also include a first KVM+ connection enabled by the first set of communication traces and a second KVM+ connection enabled by the second set of communication traces. The KVM+ connections may communicate data relating to keyboard, mouse, video, and Universal Serial Bus (USB) input by a user between any module card and the first or second switch matrix cards. The connections for a user keyboard, mouse, video, and USB may be made available to a user via the faceplates of the first or second matrix switch cards.

The backplane may further accept a plurality of module cards 114A-H through high-density multiple-contact connectors 108A-H. The same high-density multiple-contact connector pin layout and construction may be used across all module cards. Module cards may provide a variety of functions to the communications data center. The module cards may include virtual or dedicated server module cards, radio frequency communication module cards (e.g., supporting IEEE 802.11 Wi-Fi or cellular 4G-LTE protocols), Ethernet switching module cards, integrated services router module cards, video recording and archiving module cards, and analog input or output module cards. The backplane may provide at least two Ethernet channels, a dedicated asynchronous serial channel, and KVM+ connections (keyboard, video, mouse, and USB) to each module card connected to the to backplane. It is appreciated that backplane is not limited to eight module cards as seen in FIG. 1 and may be configured to accept any number of module cards based upon specific needs of the communications data center. Specifically the backplane may be designed to accept 4, 6, or 8 module cards.

The backplane may also include a Joint Test Action Group (JTAG) connection 120 according to the IEEE 1149.1 Standard Test Access Port and Boundary-Scan Architecture, which is hereby incorporated by reference herein in its entirety. The backplane 102 may enable communication between the JTAG input port 120 and every card connected to the backplane 102 through a plurality of JTAG traces. Communication via the JTAG port enables system testing and debugging.

The backplane may also include a synchronization port 122. The synchronization port 122 may include a termination on the backplane 102 for a differential pair. The backplane 102 may receive a synchronization signal from the synchronization port and distribute the signal via a plurality of synchronization traces to the plurality of high-density multiple-contact connectors accepting input from switch matrix cards 106A-B and module cards 108A-H. The synchronization signal may include, but is not limited to, a Pulse Per Second (PPS) signal from a Global Positioning System (GPS). The synchronization signal may be advantageously used by module cards requiring deterministic timing certainty in applications such as measuring vehicle analog signals in a heavy rail transportation application.

The backplane may also include fan ports 116A-B that provides power or control signals to fans 128A-B. The fan 128A or 128B may include a plurality of fan units grouped together to form a fan card. The fan card may be constructed to have the same dimensions as a power supply card, switch matrix card, or module card. The corresponding fan port 116A or 116B on the backplane 102 may include a high-density multiple-contact connector and the corresponding high-density multiple contact connector of the fan card may connect directly into fan port 116A or 116B on the backplane 102. For example, the fan port 116A or 116B on the backplane 102 may be a socket and the corresponding plug may be affixed to the fan card. The fans may be arranged to circulate air around the cards installed in the backplane to lower the temperature of cards operatively connected to the backplane during operation. The fans may be further arranged to push air towards an enclosure that surrounds the backplane to facilitate heat transfer from the cards installed in the backplane to the enclosure. It is appreciated that the fans do not have to be grouped into a fan card and subsequently the fan port does not have to be a high-density multiple-contact connector. The fans may be installed to in the environment surrounding the backplane (e.g., an enclosure) and operatively connected to the fan port 116A or 116B on the backplane or on a port on the faceplate of any card.

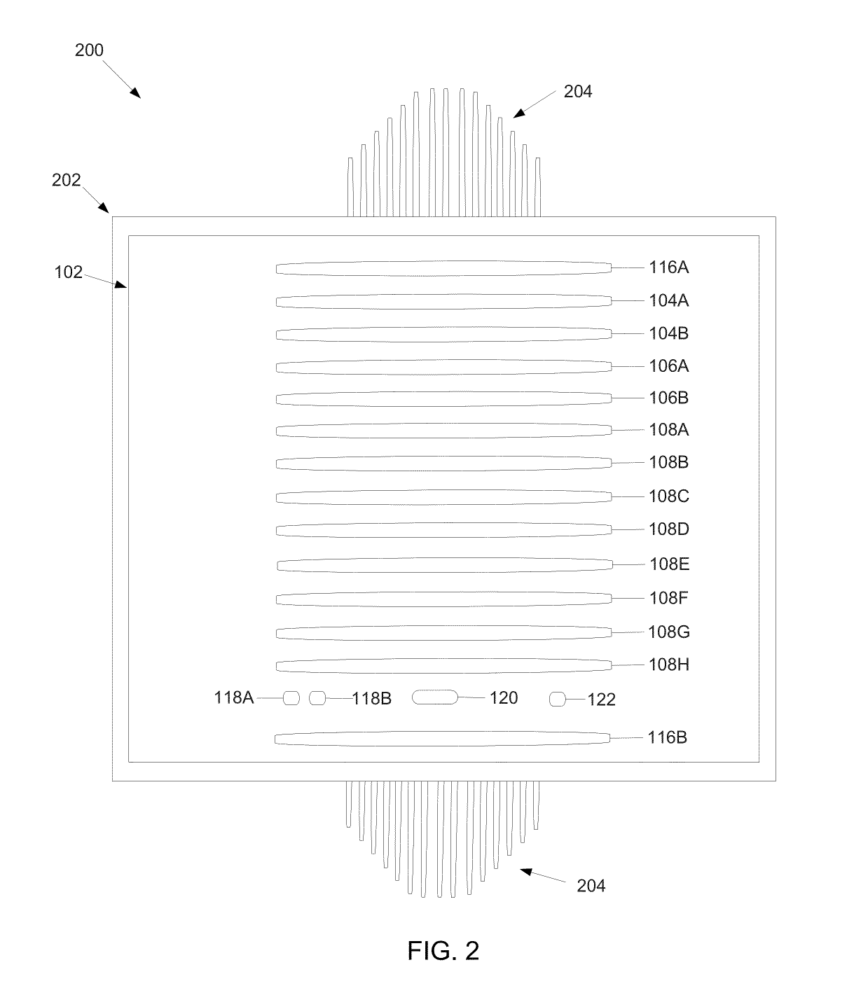

In another embodiment, the backplane 102 is affixed within a ruggedized enclosure. The ruggedized enclosure may be designed to protect the backplane and its corresponding cards from exposure to environmental elements including, but not limited to, temperature, humidity, water, vibration, and debris. FIG. 2 illustrates such an embodiment of the ruggedized enclosure. As shown, FIG. 2 includes the backplane and corresponding ports or connectors of FIG. 1, a ruggedized enclosure 202, and a heat sink 204. Alternatively, the exterior surface of the ruggedized enclosure 202 may provide sufficient direct thermal radiation capacity so as to obviate need for an explicit heat sink 204.

The backplane and ruggedized enclosure assembly 200 in FIG. 2 may include a ruggedized enclosure 202. The ruggedized enclosure 202 may take the form of any variety of shapes responsive to the dimensions of the backplane 102 installed within the ruggedized enclosure. The backplane 102 may be removably coupled to a backplane support structure within the ruggedized enclosure 202. The backplane 102 may be removably coupled to the backplane support structure through a variety of mechanisms including, but not limited to, a screw and threaded hole assembly. The backplane support structure may have a plurality of threaded holes that accept screws with a matching thread pattern. The backplane 102 may have a plurality of holes at locations commensurate with the location of the threaded holes in the backplane support structure. The threaded screws may be placed through each of the plurality of holes in the backplane and screwed into each of the respective threaded holes in the backplane support structure. The threaded screws may be coated with a compound such as, but not limited to, LOCTITE to prevent loosening during vibration. The backplane support structure or backplane 102 may have bushings or washers (e.g., lock washers) to act as a buffer between the backplane 102 and the backplane support structure. The bushings may be constructed from an elastomeric material to reduce the effects of vibration on the backplane 102.

The backplane 102 within the ruggedized enclosure 202 may be accessible through a removably sealed access cover affixed to the main body of the ruggedized enclosure 202. With reference to FIG. 1, the removably sealed access cover may be affixed to the main body to enable access to the front side 134 of the data center or the back side 132 of the data center. In other embodiments, the ruggedized enclosure 202 may include a second removably secured sealed access cover attached to the main body of the ruggedized enclosure wherein to the first secured sealed access cover attached to the main body enables access to the front side 134 of the data center and the second removably sealed access cover attached to the main body of the data center enables access to the back side 132 of the data center.

The removably sealed access cover affixed to the main body of the ruggedized enclosure 202 may have at least one port installed therein facing an outward direction. The at least one port integral with the removably sealed access cover facing an outward direction may be operatively connected to a corresponding port on the backplane or faceplate of any card installed in the backplane. For example, the removably sealed access cover may have an Ethernet port that is operatively connected to the management Ethernet port 118 on the backplane 102. The ports on the removably sealed access cover may be sealed to avoid the intrusion of debris or water into the ruggedized enclosure with a compound such as, but not limited to, rubber or epoxy. Wired or fiber optic connections that exit the ruggedized enclosure do not necessarily require a port on the removably sealed access cover affixed to the main body of the ruggedized enclosure 202. Wired or fiber optic connections may leave the ruggedized enclosure through bulkhead connectors or holes in the main body of the ruggedized enclosure sealed with a compound such as, but not limited to, rubber or epoxy.

In another embodiment, the ruggedized enclosure 202 may entirely seal the backplane 102 and its installed components from the outside environment when the removably sealed access cover is closed. By virtue of providing the desired card interconnections (e.g., primary Ethernet A, primary Ethernet B, management Ethernet A, management Ethernet B, power, JTAG, synchronization, and KVM+) among data center subsystem functions by using high-density multiple-contact connectors for each card, the backplane 102 eliminates cable interconnections between subsystem modules. The result of eliminating cable interconnections is reduced complexity that facilitates close card packaging in a sealed enclosure. The sealed ruggedized enclosure may be constructed to meet national or international rating requirements. Example ruggedized enclosure ratings include, but are not limited to, National Electrical Manufacturers Association (NEMA) and International Protection (IP) ratings. For example, the sealed ruggedized enclosure may be designed to NEMA-6P and meet the requirements of IP68 relating to dirt ingress protection and water protection during ruggedized enclosure submersion using polycarbonate plastic or stainless steel metal construction. The ruggedized enclosure may further be constructed to enable the internal communications data center to operate under a wide range of ambient conditions. The ambient conditions may include temperatures ranging from −40 degrees centigrade to 74 to degrees centigrade and altitudes in excess of 3,000 meters. The individual module, power supply, and switch matrix cards may use thermal spreaders, heat pipes, or similar systems to conduct heat from components of the cards to the heat sink 204. In the case of a ruggedized enclosure 202 made from a metal having good thermal conduction and radiation properties, such as aluminum for example, the thermal spreaders or heat pipes may conduct heat from components of the cards directly to the ruggedized enclosure 202.

In another embodiment, the physical ruggedized enclosure may not seal the backplane from the outside environment. The ruggedized enclosure may contain one or more pass ways for air to enter/exit the ruggedized enclosure. These air pass ways may facilitate the cooling process and enable greater heat dissipation. The air pass ways may have a dedicated fan unit moving air into or out of the ruggedized enclosure. The fan units may have detachable filters to remove dirt and debris from air entering or exiting the ruggedized enclosure.

The ruggedized enclosure may be designed to dissipate a specific amount of heat commensurate with the cards installed in the backplane. The ruggedized enclosure may more specifically be designed to dissipate 50 Watts of heat for each card installed in the backplane. The dissipation of heat may be accomplished through the addition of heat sinks 204 to the ruggedized enclosure. The ruggedized enclosure may further be constructed out of a material or a combination of materials with superior heat transfer properties such as, but not limited to, aluminum and copper. It is appreciated that the heat sinks 204 need not be directly affixed to the ruggedized enclosure as shown in FIG. 2. The heat sinks may be located a distance away from the main body of the ruggedized enclosure and affixed to the main body of the ruggedized enclosure through heat pipes. The heat pipes may transfer heat from the main body of the ruggedized enclosure to the heat sink located a distance away from the main body of the ruggedized enclosure.

The ruggedized enclosure may also use water cooling techniques in addition to or in place of the air cooling techniques previously described. The ruggedized enclosure may have passageways within the walls enabling a liquid coolant to pass between the walls of the ruggedized enclosure. The liquid coolant may include, but is not limited to, water or any other fluid. Heat may be transferred from the walls of the ruggedized enclosure to the liquid coolant circulating within the ruggedized enclosure walls. The liquid coolant may then remove heat from the ruggedized enclosure to a radiator located some distance away from the main body of the ruggedized enclosure.

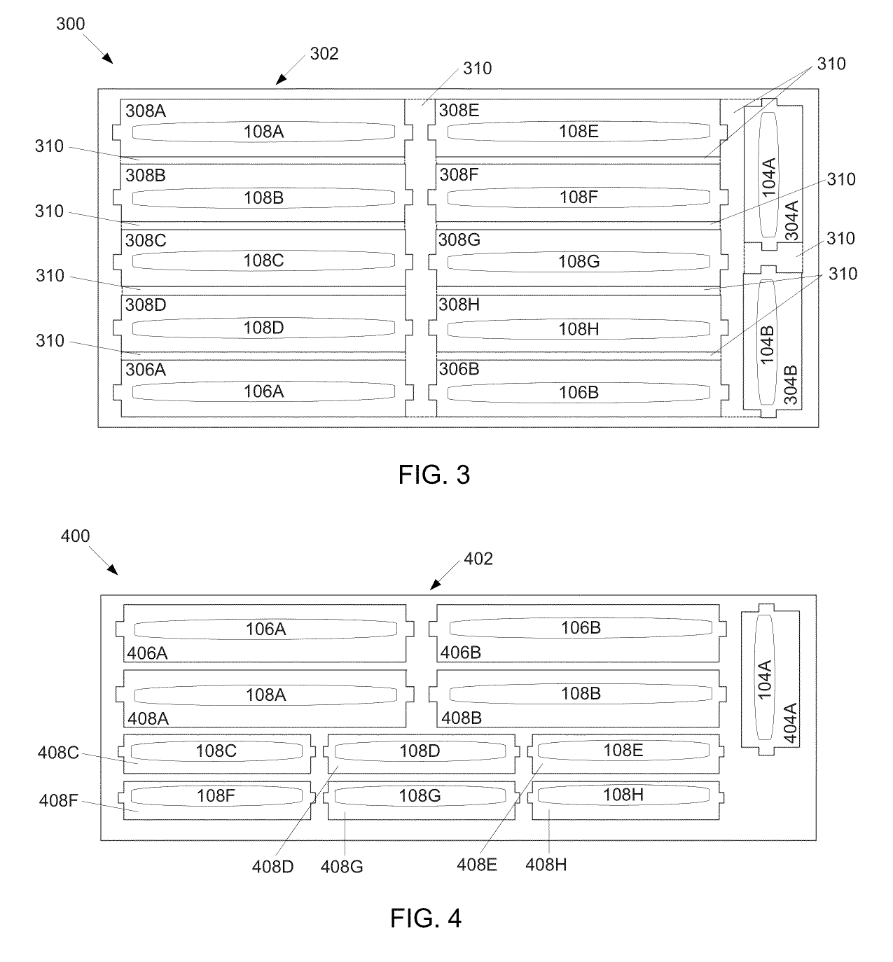

In various embodiments, the backplane 102 is affixed within a ruggedized enclosure to without the dedicated use of a heat sink or fan units. The ruggedized enclosure may be designed to protect the backplane and its corresponding cards from exposure to environmental conditions including, but not limited to, temperature, humidity, water, vibration and debris. FIG. 3 illustrate such an embodiment of the ruggedized enclosure. As shown, FIG. 3 includes a ruggedized enclosure 302, power supply card slots 304A-B, switch matrix card slots 306A-B, and module card slots 308A-H, and heat spreaders 310. The ruggedized enclosure 302 also includes backplane and corresponding ports or connectors of FIG. 1.

The slots 304A-B, 306A-B, and 308A-H in the ruggedized enclosure 302 are receptacles in the ruggedized enclosure that accept and store cards. In addition, the slots 304A-B, 306A-B, and 308A-H may properly align each card inserted into the corresponding high-density multiple-contact connector 104A-B, 106A-B, and 108A-H in the backplane for the card. The slots 304A-B, 306A-B, and 308A-H may be formed with heat spreaders 310, constructed out of a material with good thermal conduction and radiation properties, removably installed in the ruggedized enclosure between each card. Alternatively, the ruggedized enclosure 302 and heat spreaders 310 may be formed out of a single continuous piece of material (e.g., machined from a solid block of aluminum or cast in a mold). In addition, the ruggedized enclosure 302 or heat spreaders 310 may have a thermal paste or a thermal compound to facilitate heat transfer between the cards and the ruggedized enclosure or heat spreaders.

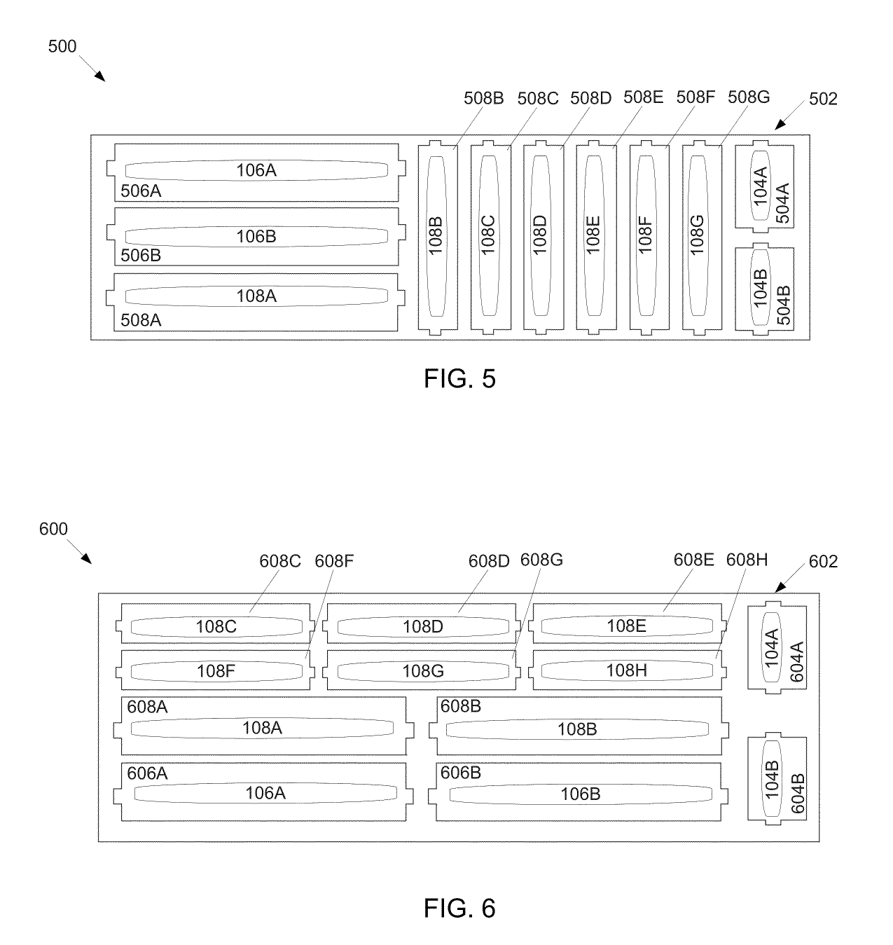

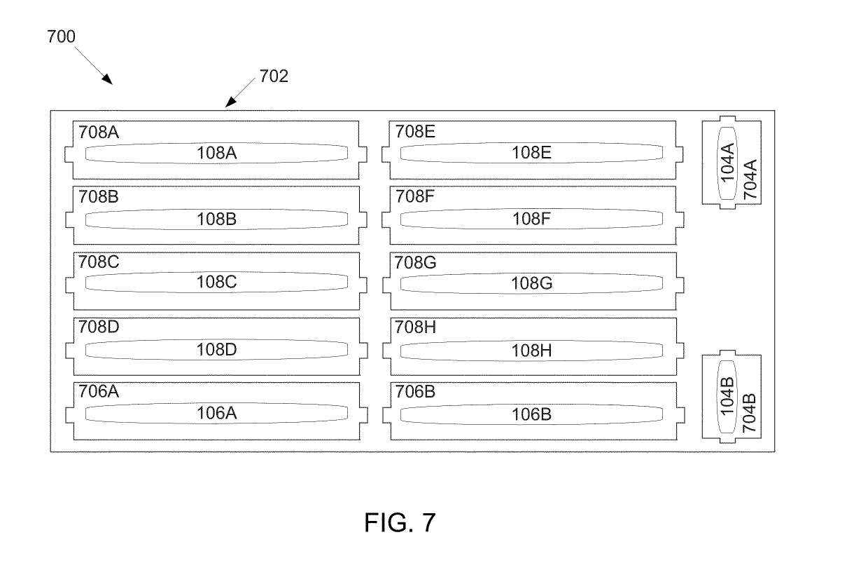

It is appreciated that the specific dimensions and design of the slots may vary based upon the design of the corresponding card type the slot is configured to accept. It is further appreciated that the specific dimensions of the ruggedized enclosure may vary with both the number of slots and the dimension of each slot. FIGS. 4-7 illustrate additional ruggedized enclosure designs and subsequent card form factors. The designs illustrated in FIGS. 4-7 are not an exhaustive illustration of all of the possible combinations or designs. As shown, each figure in FIGS. 4-7 a ruggedized enclosure 402, 502, 602, and 702, power supply card slots 404A, 504A-B, 604A-B, and 704A-B, switch matrix card slots 406A-B, 506A-B, 606A-B, and 706A-B, and module card slots 408A-H, 508A-G, 608A-H, and 708A-H. The ruggedized enclosure 402, 502, 602, and 702 also includes the backplane and corresponding ports or connectors of FIG. 1.

The backplane and subsequent ruggedized enclosure may be structured to dispose the high-density multiple-contact connectors for the power supply cards 104A-B and subsequent to slots 304A-B, 404A, 504A-B, 604A-B, and 704A-B near the edge of the ruggedized enclosure 302, 402, 502, 602, and 702 to facilitate heat transfer from the power supply cards to the ruggedized enclosure 302, 402, 502, 602, and 702. The specific form factor of the power supply card may vary based upon its characteristics, such as a power rating of the power supply card. For example, a power supply card with a higher power rating may dissipate more heat and require a larger form factor as illustrated by figure elements 304A-B and 404A. In contrast, a power supply card with a lower power rating may dissipate less heat and consequently operate in a smaller form factor as illustrated by figure elements 504A-B, 604A-B, and 704A-B. The backplane and subsequent ruggedized enclosure may be further structures to dispose card types that dissipate less heat closer to the center of the ruggedized enclosure and card types that dissipate more heat closer to the edges of the ruggedized enclosure. It is appreciated that the module cards may dissipate various amounts of heat based upon the specific function of the module card and may consequently require different form factors. For example, module cards that dissipate more heat may require a larger form factor and consequently a larger slot size as illustrated by figure elements 308A-H, 408A-B, 508A, 608A-B, and 708A-H. In contrast, module cards that dissipate less heat may be packed closer together with a smaller form factor and consequently a smaller slot size as illustrated in figure elements 408C-H, 508B-G, and 608C-H.

Having thus described several aspects of at least one example, it is to be appreciated various alterations, modification, and improvements will readily occur to those skilled in the art. For example, it should be appreciated that depending on the specific requirements in which the communications data center is used, the communications data center may include different numbers and types of cards. For example depending on the requirements, some implementations may include two power supply cards but only a single switch matrix card and only a single module card, while other implementations may include only a single power supply card, but multiple switching matrix cards and multiple module cards. Moreover, it should be appreciated that in certain environments, such as a hospital, the communications data center backplane may be installed in a conventional data center rack without the use of the ruggedized enclosure. Such alterations, modifications, and improvements are intended to be part of this disclosure, and are intended to be within the scope of the embodiments disclosed herein. Accordingly, the foregoing description and drawings are by way of example only.

What is claimed is:

1. A ruggedized communications data center comprising:
a ruggedized enclosure having a main body and including
a removably secured sealed access cover affixed to the main body;
a backplane support structure within the main body; and
a backplane removably coupled to the backplane support structure within the main body, the backplane including
a plurality of connectors to removably connect with a plurality of cards, the plurality of connectors including at least one connector to connect to a power supply card, at least one connector to connect to a switch matrix card, and at least one connector to connect to a module card;
a first plurality of electrical connections to electrically connect a power supply card with a switch matrix card and a module card; and
a second plurality of electrical connections to electrically connect a switch matrix card with a one module card.

2. The ruggedized communications data center as claimed in claim 1, wherein the backplane comprises a printed circuit board and includes
a first high-density multiple-contact connector configured to removably connect with a power supply card;
a second high-density multiple-contact connector configured to removably connect with a switch matrix card;
a third high-density multiple-contact connector configured to removably connect with a module card;
a plurality of power distribution traces arranged to distribute power from the first high-density multiple-contact connector to the second high-density multiple contact connector and the third high-density multiple contact connector; and
a plurality of communication traces arranged to operatively connect the second high-density multiple-contact connector and the third high-density multiple-contact connector.

3. The ruggedized communications data center as claimed in claim 2, wherein the backplane is a passive backplane.

4. The ruggedized communications data center as claimed in claim 2, wherein the backplane further includes at least one fan port.

5. The ruggedized communications data center as claimed in claim 2, wherein the backplane further includes a serial port.

6. The ruggedized communications data center as claimed in claim 2, wherein the plurality of power distribution traces are arranged in a star configuration from the first high-density multiple-contact connector to the second high-density multiple-contact connector and the third high-density multiple-contact connector.

7. The ruggedized communications data center as claimed in claim 6, wherein the plurality of communication traces are arranged in a star configuration from the second high-density multiple-contact connector to the first high-density multiple-contact connector and the third high-density multiple-contact connector.

8. The ruggedized communications data center as claimed in claim 3, further comprising the module card and wherein the module card is a first module card and the backplane further includes a fourth high-density multiple-contact connector configured to receive input from a second module card.

9. The ruggedized communications data center as claimed in claim 1, wherein the ruggedized enclosure is constructed from aluminum.

10. The ruggedized communications data center as claimed in claim 1, wherein the ruggedized enclosure further includes a heat sink affixed to the main body of the ruggedized enclosure.

11. The ruggedized communications data center as claimed in claim 1, wherein ruggedized enclosure further includes a heat sink designed to dissipate 50 Watts of heat per card installed in the backplane.

12. The ruggedized communications data center as claimed in claim 1, wherein the ruggedized enclosure is designed to enable communications data center operation during ambient temperatures ranging from −40 degrees centigrade to 74 degrees centigrade.

13. The ruggedized communications data center as claimed in claim 1, wherein the ruggedized enclosure is designed to enable communications data center operation in altitudes in excess of 3,000 meters.

14. The ruggedized communications data center as claimed in claim 1, wherein the removably sealed access cover affixed to the main body of the ruggedized enclosure includes at least one port.

15. The ruggedized communications data center as claimed in claim 14, wherein the backplane includes at least one port operatively connected to the at least one port of the removably sealed access cover.

16. The ruggedized communications data center as claimed in claim 14, wherein the at least one port of the removably sealed access cover includes an Ethernet port.

17. The ruggedized communications data center as claimed in claim 1, wherein the ruggedized enclosure further includes heat pipes and a heat sink.

18. The ruggedized communications data center as claimed in claim 17, wherein the heat sink is located a distance from the main body.

19. The ruggedized communications data center as claimed in claim 18, wherein the heat pipes are operatively connected to the heat sink located some distance from the ruggedized enclosure.

20. The ruggedized communications data center as claimed in claim 1, wherein the ruggedized enclosure is sealed from outside debris and humidity.

21. A communications center backplane comprising:
a plurality of connectors to removably connect with a plurality of cards, the plurality of connectors including at least one first connector having a power channel and a communication channel to connect to a power supply card, at least one second connector having a power channel and a communication channel to connect to a switch matrix card, and at least one third connector having a power channel and a communication channel to connect to a module card;
a first plurality of electrical connections to electrically connect the power channel of the at least one first connector to the power channel of the at least one second connector and the power channel of the at least one third connector; and
a second plurality of electrical connections to electrically connect the communication channel of the at least one second connector with the communication channel of the at least one first connector and the communication channel of the at least one third connector.
